(19) United States
(12) Patent Application Publication
(10) Pub. No.: US 2025/0246519 A1
(43) Pub. Date: Jul. 31, 2025

(54) INTEGRATED CIRCUIT DIE STACK WITH A DUAL-SIDED BRIDGE DIE

(71) Applicant: Advanced Micro Devices, Inc., Santa Clara, CA (US)

(72) Inventors: Arsalan ALAM, Austin, TX (US); Chandra Sekhar MANDALAPU, Lehi, UT (US); Liwei WANG, Austin, TX (US); Manish DUBEY, Austin, TX (US); Omkar Deepak GUPTE, Austin, TX (US); Sri Ranga Sai BOYAPATI, Austin, TX (US); Sai VADLAMANI, Austin, TX (US)

(21) Appl. No.: 18/424,158

(22) Filed: Jan. 26, 2024

(51) Int. Cl. H01L 23/482; H01L 23/00; H01L 23/498; H01L 25/065

(52) U.S. Cl. CPC H01L 23/4821; H01L 23/49816; H01L 23/49822; H01L 24/05; H01L 24/13; H01L 25/0652; H01L 2224/05009; H01L 2224/05025; H01L 2224/13009; H01L 2224/13024; H01L 2924/1431; H01L 2924/1434; H01L 2924/15311

(57) ABSTRACT

Disclosed herein are a dual-sided bridge die, an integrated circuit die package assembly having the dual-sided bridge die, and a method for fabricating the integrated circuit die package assembly. A dual-sided bridge die includes a substrate; a first redistribution layer built on a top surface of the substrate and configured to couple with a bottom surface of a first integrated circuit die; and a second redistribution layer built on a bottom surface of the substrate and configured to couple with a top surface of a second integrated circuit die. The top surface and the bottom surface of the substrate are respectively disposed on opposite sides of the substrate.

### TECHNICAL FIELD

Embodiments of the present invention generally relate to an integrated circuit die stack with a dual-sided bridge die, and, more particularly, relate to an integrated circuit die stack with a dual-sided bridge die capable of providing lateral communication for integrated circuit dice at both a lower tier and a higher tier.

### BACKGROUND

Electronic devices, such as tablets, computers, copiers, digital cameras, smart phones, control systems and automated teller machines, among others, often leverage chip package assemblies for increased functionality. To increase processing capabilities, chip packaging schemes often form a die stack by vertically mounting a plurality of integrated circuit dice to a package substrate. The integrated circuit die stack may include integrated circuit dice for memory, logic, communication, power management, or other functions.

In an integrated circuit die stack, integrated circuit dice of the same tier or different tiers often need to communicate with each other at a high speed and with high integrity. The current designs of die stacks have not provided effective solutions for such high speed and high integrity lateral communications.

Therefore, a need exists for an improved integrated circuit die stack.

### SUMMARY

Disclosed herein are a dual-sided bridge die, an integrated circuit die package assembly having the dual-sided bridge die, and a method for fabricating the integrated circuit die package assembly. A dual-sided bridge die includes a substrate; a first redistribution layer built on a top surface of the substrate and configured to couple with a bottom surface of a first integrated circuit die; and a second redistribution layer built on a bottom surface of the substrate and configured to couple with a top surface of a second integrated circuit die. The top surface and the bottom surface of the substrate are respectively disposed on opposite sides of the substrate.

According to an embodiment, the integrated circuit die package assembly includes a package substrate; and an integrated circuit die stack. The integrated circuit die stack includes a plurality of integrated circuit dice disposed at a first tier of the integrated circuit die stack; a plurality of integrated circuit dice disposed at a second tier that is stacked vertically above the first tier; and a plurality of integrated circuit dice disposed at a third tier that is stacked vertically above the second tier. The plurality of the integrated circuit dice at the second tier include a dual-sided bridge die configured to provide lateral communication for at least two dice of the first tier and provide lateral communication for at least two dice of the third tier.

According to another embodiment, an integrated circuit die package assembly includes a package substrate; and an integrated circuit die stack disposed above the package substrate. The integrated circuit die stack includes a plurality of first tier-one integrated circuit die and a second tier-one integrated circuit die disposed at a first tier of the integrated circuit die stack. The integrated circuit die includes a dual-sided bridge die disposed at a second tier that is stacked vertically above and partially overlapped with the first and second tier-one integrated circuit dice. The integrated circuit die further includes a first tier-three integrated circuit die disposed at a third tier that is stacked vertically above and partially overlapped with the dual-sided bridge die disposed at the second tier. The dual-sided bridge die is configured to provide lateral communication for between at least first tier-one integrated circuit die and the first tier-three integrated circuit die.

According to an embodiment, the method of making an integrated circuit die package assembly includes mounting a plurality of integrated circuit dice of a first tier on a first tier; arranging a plurality of integrated circuit dice of a second tier on top of the integrated circuit dice of the first tier, the plurality of the integrated circuit dice of the second tier comprising a dual-sided bridge die; arranging a plurality of integrated circuit dice of a third tier on top of the integrated circuit dice of the second tier; forming an integrated circuit die stack by connecting the integrated circuit dice of the first, second, and third tiers, and mounting the integrated circuit die stack on a package substrate. The connecting comprises connecting the dual-sided bridge die with at least two integrated circuit dice of the first tier and at least two integrated circuit dice of the third tier;

According to an embodiment, the method of making an integrated circuit die package assembly includes mounting a dual-sided bridge die to a first tier-one integrated circuit die and a second tier-one die, the first and second tier-one dice defining a first tier, the dual-sided bridge die defining a second tier; mounting a first tier-three integrated circuit die of a third tier on the dual-sided bridge die to form an integrated circuit die stack; and mounting the integrated circuit die stack on a package substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1a illustrates a schematic cross-sectional view of an electronic device having an integrated circuit die stack with a dual-sided bridge die according to an embodiment of the present application.

FIG. 1b illustrates a schematic top view of an IC die stack, according to an embodiment of the present application.

FIG. 2a illustrates a schematic close-up view of a three tier IC die stack having a dual-sided bridge die at each tier, according to an embodiment of the present application.

FIG. 2b illustrates a schematic close-up view of a three tier IC die stack having dual-sided bridge dies at both the first tier and the third tier, according to an embodiment of the present application.

FIG. 2c illustrates a schematic configuration of an IC die stack comprising a dual-sided bridge die coupling with other die stacks, according to an embodiment of the present application.

FIG. 3a is a schematic cross-sectional view of a dual-sided bridge die having a passive device according to an embodiment of the present application.

FIG. 3b illustrates a schematic cross-sectional view of another dual-sided bridge die having a passive device, according to an embodiment of the present application.

FIG. 3c illustrates a schematic cross-sectional view of another dual-sided bridge die having an active device, according to an embodiment of the present application.

FIG. 4 illustrates a schematic manufacturing process for making a dual-sided bridge die, according to an embodiment of the present application.

FIG. 5 illustrates a schematic manufacturing process for making a bridge die having two redistribution layers, according to an embodiment of the present application.

FIG. 6 illustrates a schematic manufacturing process for making an IC die stack having a dual-sided bridge die, according to an embodiment of the present application.

FIG. 7 illustrates a method for making an integrated circuit die package assembly having a dual-sided bridge die, according to an embodiment of the present application.

To facilitate understanding, identical reference numerals have been used, where possible, to designate identical elements that are common to the figures. It is contemplated that elements of one embodiment may be beneficially incorporated in other embodiments.

### DETAILED DESCRIPTION

A dual-sided bridge die having two redistribution layers are disclosed. The dual-sided bridge die is capable of providing lateral communication among integrated circuit dices of both a lower tier and a high tier. The dual-sided bridge die is configured to comprise passive devices, such as capacitors, adjacent to the input and/or output routings of the dual-sided bridge die. The dual-sided bridge die may also comprise active devices, such as active circuitries. A chip package using a dual-sided bridge die includes redistribution layers built up on the top and bottom surfaces of a substrate, such as silicon, glass, or any other suitable substrate. The redistribution layer at the top surface couples with other integrated circuit dice disposed in a higher tier via connections of a high density, such as thermal compression bonds, hybrid bonds, microbumps, or any other suitable connections. The redistribution layer at the bottom surface couples with other integrated circuit dice disposed in a lower tier via connections of a high density, such as thermal compression bonds, hybrid bonds, microbumps, or any other suitable connections. Pitches of the hybrid bonds are denser than connections made by wire bonds or solder balls, thus enabling high density, high speed data transmission. The integrated passive and/or devices, such as a capacitor and an active circuitries, may be included in the redistribution layer or the substrate. Having connections on both sides of the dual-sided bridge die also enables warpage reduction by increasing the mechanical rigidity of the chip package architecture, making the chip package more robust and reliable. Further, the dual-sided bridge die shortens routing distances between IC dice within the chip package, thus increasing processing speeds while advantageously improving signal integrity.

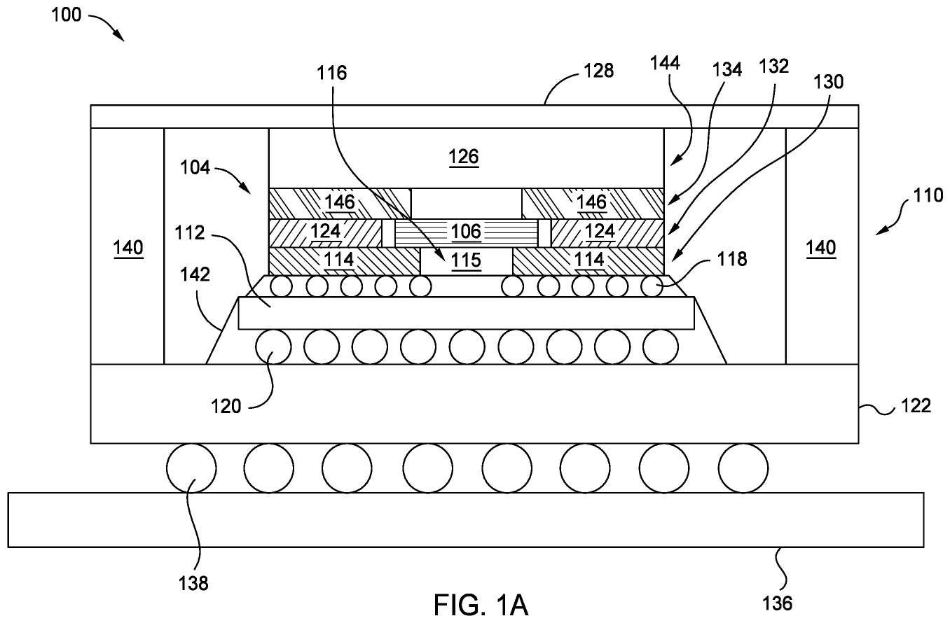

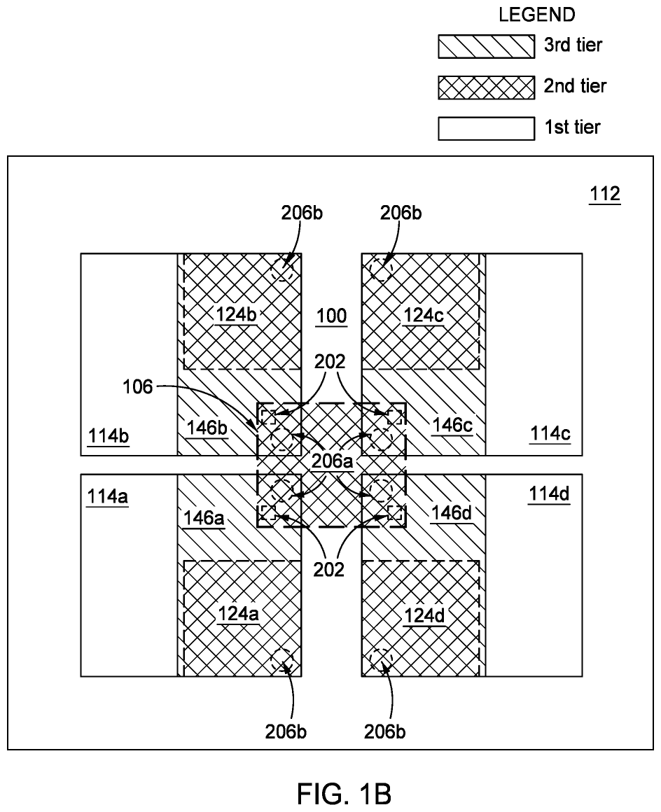

Turning now to FIG. 1a, an exemplary integrated circuit (IC) die package assembly 110 is disposed on a printed circuit board (PCB) 136 and is connected with the PCB 136 via a plurality of electric connections 138, such as solder balls or other suitable connections. The IC die package assembly 110 and the PCB 136 together form at least part of an electronic device 100. The electronic device 100 may be a tablet, computer, copier, digital camera, smart phone, control system, automated teller machine, server or other solid-state memory and/or logic device.

The IC die package assembly 110 includes an IC die stack 104 mounted to an optional interposer 112. According to an embodiment, the IC die stack 104 may be mounted directed to a package substrate 122. The IC die package assembly 110 further includes an optional stiffener 140 coupled with the package substrate 122 and configured to enhance the warpage resistance of the package substrate 122 against out of plane deformation. The IC die package assembly 110 further includes a lid 128 configured to cover the IC die stack 104 and dissipate heats generated by the IC die package assembly 110.

The IC die stack 104 includes a plurality of tiers of IC dice stacked vertically on top of each other. For example, four tiers of IC dice are shown in FIG. 1a: a first tier 130, a second tier 132, a third tier 134, and fourth tier 144. The IC dice of a same tier are configured to be substantially co-planar with each other. According to an embodiment, the IC die stack 104 is not limited to just four tiers of IC dice and may include five (5), or even a greater number of tiers of IC dice. IC dice disposed at the first tier 132 include two IC dice 114. The dice 114 at the first tier 130 may be directly coupled with the interposer 112 or the package substrate 122. Connections among the IC dice of the plurality of tiers may include solder balls, microbumps, thermal compression bonds, hybrid bonds, through silicon vias, or another other suitable connections.

As shown in FIG. 1a, two IC dice 124 and a dual-sided bridge die 106 are disposed at the second tier and stacked vertically above the IC dice 114. According to an embodiment, the two IC dice 114 in the lower tier are configured to communicate with each other via the dual-sided bridge die 106 disposed at the second tier 132. The two IC dice 114 may also communicate with each other via the interposer 112. According to an embodiment, the dual-sided bridge die 106 includes a plurality of integrated passive and/or active devices, such as capacitors, inductors, and active circuitries.

The number of dice disposed of each tier is not limited to two (2) or three (3) dice as shown in FIG. 1a. Each tier may include a greater number of dice, such as four (4), six (6), ten, or even a greater number of dice. The IC dice of the same tier may include a single IC die, an IC die stack, or a combination thereof.

FIG. 1a also illustrates relative dimensions of IC dices in different tiers, according to an embodiment. The length of each die is shown in a horizontal direction, while the height of each die is shown in a vertical direction. In one example, the dual-sided bridge die 106 disposed at the second tier 132 couples with IC dice 114 of the first tier 130. As a result, the length of the dual-sided bridge die 106 is greater than the length of the gap 115 formed among the IC dice 114. Each IC dice 114 may overlap with both the dual-sided bridge die 106 and an IC die 124. In an example, the length of the top surface of the IC die 114 is configured to be greater than the length of the bottom surface of the IC dice 124, such that the bottom surface of the IC die 124 is entirely mounted on the top surface of the IC die 114. Thus, each of the IC dice 114 may have a larger size than the IC dice 124. For example, the IC die 114 has a top surface area (length×width) that is greater than a bottom surface of the IC die 124.

In one embodiment, the dual-sided bridge die 106 and the IC dice 124 are coupled to the IC dice 114 via a plurality of hybrid bonds. The dual-sided bridge die 106 is configured to provide a high speed and high integrity data transmission between dice 114 disposed at the first tier 130.

In the exampled depicted in FIG. 1a, two IC dice 146 are disposed at the third tier 134 and stacked vertically above the IC dice 124 and the dual-sided bridge die 106. According to an embodiment, the two IC dice 146 at the third tier 134 are configured to communicate with each other via the dual-sided bridge die 106 disposed at the second tier 132. In an embodiment, the dual-sided bridge die 106 includes routing connections and hybrid bonds at both the top and bottom surfaces for connecting with the IC dice 114 and 146. The use of hybrid bonds reduces contact pitch, which Having bonds at both the top and bottom surfaces advantageously improves stiffness of the chip package, which improves reliability of solder and other chip-to-chip connections. The dual-sided bridge die 106 allows lateral communications for a plurality of IC dice of a same tier, which is higher or lower than the dual-sided bridge die 106, which on conventional packages would need to be routed vertically down to a substrate then back up to the die. Thus, the dual-sided bridge die 106 shortens the routing distances between dice on different tiers, thus improving processing performance while improving signal integrity. The dual-sided bridge die 106 may also be configured to provide communications for IC dice of different tiers, such as between IC die 146 at the third tier and IC die 114 at the first tier.

In the example depicted in FIG. 1a, the fourth tier 144 includes a filler die 126 configured to fill the space between the third tier 134 and the lid 128. The filler die 126 is configured to raise the height of the IC die stack 104 to the same height as the stiffener 140. The filler die 126 may include a semiconductor substrate, such as a silicon substrate. In one example, the filler die 126 forms a non-conductive contact with the dice 124 and is not electrically connected to the dice 124. Again, the IC die stack 104 is not limited to only four tiers. A greater or lesser number of tiers of IC dice may be included in the IC die stack 104. In addition, a greater or less number of IC dice may be included in each tier. In another example, the fourth tier 144 may include a plurality of IC dice, which may include a dual-sided bridge die.

The IC dice 114, 124, and 146 may be programmable logic devices, such as field programmable gate arrays (FPGA), memory devices, optical devices, processors or other IC logic structures. The interconnection among IC dice of different tiers may include hybrid bonds, or micro solder balls. The IC die stack 104 mounted to a top surface of the interposer 112 by die connections 118. The die connections 118 may be in the form of a plurality of solder joints, also known as “micro-bumps.”

The interposer 112 includes a circuitry for electrically connecting the IC die stack 104 to a circuitry of the package substrate 122. Solder connections 120, also known as or “package bumps” or “C4 bumps,” are utilized to provide an electrical connection between the circuitry of the interposer 112 and the circuitry of the package substrate 122. The package substrate 122 may be mounted and connected to the PCB 136, utilizing solder balls 138, sockets, wire bonding or other suitable technique.

An under molding 142 may be utilized to fill the space not taken by the solder connections 120 between the PCB 136 and the interposer 112 or the package substrate 122. A gap fill material 116 may be utilized to fill gaps within the IC die stack 104.

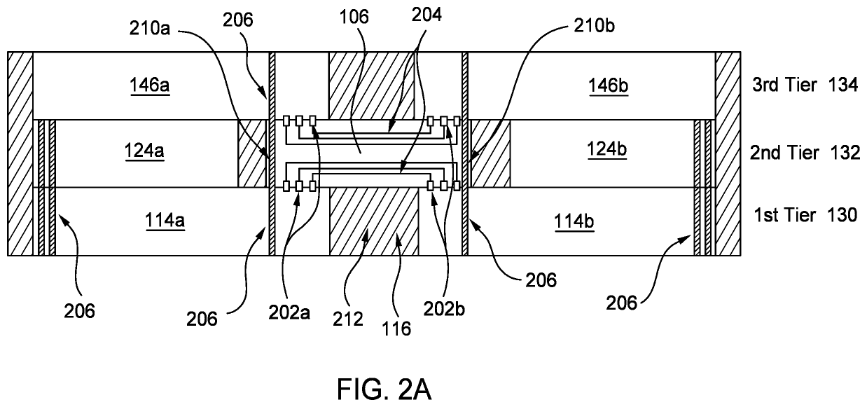

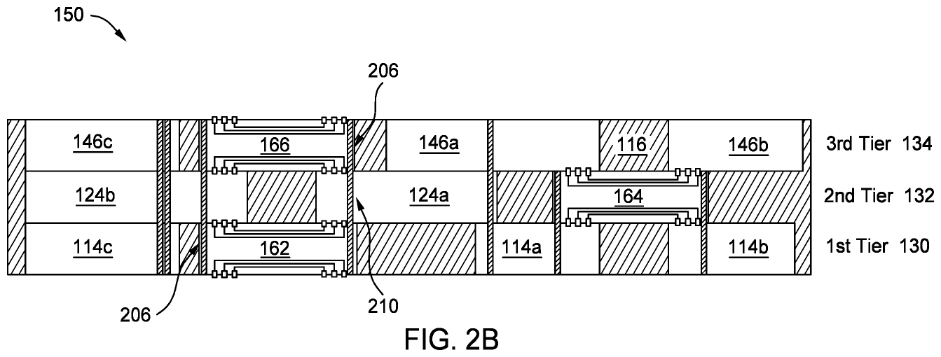

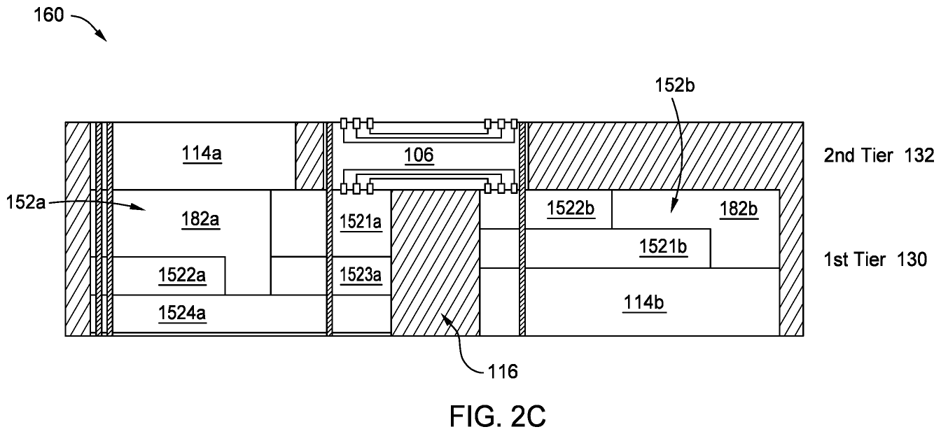

FIG. 1b illustrates a schematic top view of the IC die stack 104, according to an embodiment. A plurality of IC dice are mounted on the interposer 112. The plurality of IC dice include: at the first tier, IC dice 114a, 114b, 114c, and 114d; at the second tier, IC dice 124a, 124b, 124c, 124d, and the dual-sided bridge die 106; and at the third tier, IC dice 146a, 146b, 146c, and 146d. FIG. 2 also includes legends displaying filling paters for IC dice or each tier. The filler die 126 is not shown in FIG. 1b. The dual-sided bridge die 106 is disposed between the IC dice 146 and the IC dice 114 and configured to provide data communications among the IC dice 146 and among the IC dice 114. The IC dice may be separated by the gaps 115. The IC dice may communicate with each other via the interposer 112 and/or the dual-sided bridge die 106. The IC dice 114a, 114b, 114c and 114d couple with a plurality of IC dice of the second tier. For example, two IC dice 124a and 124c are mounted on the top surface of the IC die 114a and 114c, respectively. In an embodiment, an IC die may couple with the interposer 112 and not directly couple with any other IC die.

In an embodiment, IC dice 114a-d are coupled with the dual-sided bridge die 106 to have a high speed and high integrity communication. As shown in FIG. 1b, a portion of each of the IC dice 114a-d are disposed under and overlaps a portion, such as a corner, of the dual-sided bridge die 106. Hybrid bonds 202 electrically and mechanically connect the overlapped portions of the IC dice 114a-d and the dual-sided bridge die 106 to enable communication therebetween while also increasing the warpage resistance of the chip package. For example, the IC die 114a at the first tier may communicate with any of the IC dice 114b, 114c, and 114d via the dual-sided bridge die 106. IC dice 146a and 146b at the third tier are also coupled with the dual-sided bridge die 106 to have a high speed and high integrity communication. As shown in FIG. 1b, a portion of each of the IC dice 146a, 146b are disposed over and overlaps a portion, such as a corner, of the dual-sided bridge die 106. Hybrid bonds 202 electrically and mechanically connect the overlapped portions of the IC dice 146a, 146b and the dual-sided bridge die 106 to enable communication therebetween while also increasing the warpage resistance of the chip package. Thus, dual-sided bridge die 106 is capable of providing a faster and more robust data communication than the interposer 112 as the routing distances between dice are shortened via the dual-sided bridge die 106.

As discussed above, the dual-sided bridge die 106 couples with the plurality of IC dice 114a-d and 146a-b via hybrid bonds 202. Hybrid bonds 202 are disposed at both the top and bottom surfaces of the dual-sided bridge die 106. The hybrid bonds includes metal-to-metal bonds formed by a hybrid bonding process. For example, the metal-to-metal bonds may be formed using pressure and heat to form eutectic metal bonds. A hybrid bond may be formed by bonding the dielectric materials surrounding bond pads to first secure IC dice, followed by an interfusion of the metal materials of the bond pads to create the electric interconnect. The dielectric materials surrounding the bond pads is selected from a material suitable for hybrid bonding to another dielectric material. Materials that are suitable for hybrid bonding include polybenzoxazole (PBO), polyimide (PI), benzocyclobutene (BCB), a combination thereof, or the like. According to an embodiment, the pitch among the hybrid bonds 202 is less than 10 μm, 5 μm, or 1 μm. The hybrid bonds of the dual-sided bridge die 106 provides a significantly denser pitch of connections than wire bonds or micro solder balls. As a result, the communication bandwidth between the hybrid bonded IC dice is significantly greater than conventional devices. Other connections, such as thermal compression bonds and microbumps, may also be used to couple the dual-sided bridge die with other IC dice.

In an embodiment, the hybrid bonds 202 of the dual-sided bridge die 106 couple with each other via a plurality of routing connections 204 (shown in FIG. 2). The plurality of routing connections 204 may include metal traces formed in a buildup layer. The routing connections 204 terminate at the hybrid bond pads that are configured to form one side of the hybrid bonds 202.

As shown in FIG. 1b, the IC dice may include a plurality of through silicon vias (TSVs) 206, such as 206a and 206b. The TSVs 206a connect the bridge die 106 with IC dice at both the first tier and the third tier. The TSV 206b connect the IC dice 124a, 124b, 124c, and 124d at the second tier with IC dice 114a, 114b, 114c, and 114d at the first tier. The TSVs 206 provides vertical connectivity for IC dice of different tiers. The TSVs 206 may transfer several types of signals, including power, ground connection, data signal, testing signals, control signal, timing signal, encryption signal, or any other signals transmitted from a die to another die. The dual-sided bridge die 106 may also include a plurality of TSVs 210 that couple with the adjacent tiers of other IC dice. Having TSVs 206a in the dual-sided bridge die 106 increases design flexibility by not restricting TSVs only to certain areas of the IC dices of tiers adjacent to the adjacent dual-sided bridge die 106. Stated differently, the ability to used TSVs 206a in addition to TSVs 206b enables greater flexibility in locating power, ground and signal transmission routing, which ultimately improves signal integrity and device performance.

FIG. 2a illustrates a schematic configuration of the first, second, and third tiers of the IC die stack 104, according to an embodiment. As described above, the dual-sided bridge die 106 is disposed at the second tier 132. The bottom side of the dual-sided bridge die 106 is coupled with two dice 114a and 114b disposed at the first tier 130. The top surface of the dual-sided bridge die 106 is coupled with two dice 146a and 146b disposed at the third tier 134. Comparing to a single-sided bridge die having connections at only one of the bottom or top surfaces, the dual-sided bridge die 106 has better warpage resistance due the mechanical connections at both the bottom and top surfaces. A dual-sided bridge die 106 is also capable of providing more connections and higher speed than a single-sided bridge die.

In an example, the bottom surface of the dual-sided bridge die 106 directly overlays and couples to the dice of the lower tier, while the top surface of the dual-sided bridge die 106 directly underlays and couples to the dice of the upper tier. The IC dice 114a and 114b may have a larger size than the IC dice 124a and 124b. The IC dice 146 and 146b may also have a larger size than the IC dice 124a and 124b. As a result, the IC die 124a is disposed entirely on the top surface of the IC die 114a or on the bottom surface of the IC die 146a. Since the IC dice 114a and 146a are larger than the IC die 124a, the IC dice 114 and 146 have enough space available for routings needed to establish high density interconnects. According to an embodiment, the dual-sided bridge die 106 and the dice 114 and 146 are coupled via a plurality of hybrid bonds 202a and 202b.

A gap 212 between the die 114a and the die 114b is filled with a gap fill material 116, such as a dielectric material. The gap fill material 116 also fills other gaps formed among the dice disposed at the second tier and the third tier. The die 114a at the first tier is not limited to couple with only 2 dice at the second tier. The die 114a may couple with 3, 4, or 5 IC dice at the second tier. According to an embodiment, at least one die at the second tier that couples with the dice 114 is configured to be a dual-sided bridge die that provides lateral data communication among the dice 114 disposed at the first tier and the dice 146 disposed at the higher tier.

According to an embodiment, the dual-sided bridge die 106 couples with the IC dice 114 and 146 via any suitable connections, such as hybrid bonds, BEOL, thermal compression bonds, or micro solder balls. The IC dice 114, 124, and 146 may also include a plurality of TSVs 206. The dual-sided bridge die 106 may also include TSVs 210a and 210b that couple with the TSVs 206. For example, the TSV 206 of the IC die 146a may be coupled with TSV 210a of the dual-sided bridge die 106, which in turn is coupled with the TSV 206 of the IC die 114a.

FIG. 2b illustrates a schematic configuration of an IC die stack 150, according to an embodiment. The IC die stack 150 includes three (3) tiers of IC dice 130, 132, and 134, respectively. One or more additional tiers of IC dice may be disposed on the first tier and/or the second tier. A dual-sided bridge die may be disposed in two or more of IC dice and configured to provide interconnection among IC dice at a lower tier and/or a higher tier, and/or to a substrate 122 or interposer 112. By having dual-sided bridge dies in multiple tiers, routing between interconnected dice in different tiers can be shortened for improved performance and increased signal integrity. For example, a dual-sided bridge die 166 together with IC dice 146a-c are disposed at the third tier 134, another dual-sided bridge die 164 together with IC dice 124a-b are disposed at the second tier 132, and another dual-sided bridge die 162 together with IC dice 114a-c are disposed at the first tier. A bottom surface of the dual-sided bridge die 166 is coupled with the IC dice 124a and 124b. A top surface of the dual-sided bridge die 166 may be coupled with the IC dice of another tier or an interposer or substrate (all not shown). The dual-sided bridge die 164 at the second tier 132 may be configured similarly as the bridged die 106 shown in FIG. 2a. A bottom surface of the dual-sided bridge die 164 is coupled with the IC dice 114a and 114b. A top surface of the dual-sided bridge die 164 is coupled with the IC dice 146a and 146b. The dual-sided bridge die 162 couple with the IC dice 124b and 124b and an interposer 112 or a package substrate 122 as the dual-sided bridge die 162 is disposed at the first tier. The dual-sided bridge die 166 may be coupled with the dual-sided bridge die 162 via the TSVs 206 and 210 for direct connection with other tiers not show without having to utilize space within the dice of other tiers.

FIG. 2c illustrates a schematic configuration of an IC die stack 160, according to an embodiment. The IC die stack 160 may have more tiers of IC dices, but FIG. 2c shows only two tiers. Comparing to the dice 114a and 114b in FIG. 2a, IC dice of the first tier 130 of the IC die stack 160 may include other die stacks, such as IC die stacks 152a and 152b, each functioning as an electronic device. For example, the IC die stack 152a includes four (4) IC dice 1521a, 1522a, 1523a, and 1524a stacked on top of each other, in which the die 1521a is connected with the dual-sided bridge die 106. The IC die stack 152b includes two (2) dice 1521b and 1522b stacked on top of each other, which, in turn, are mounted on the top surface of the die 114b. Mold compound 182a may be utilized to fill the space within the stack 152a defined between IC die 1522a and 114a. Mold compound 182a may also be utilized to fill the space within the stack 152a defined between IC die 1524a and 114a, and the space defined between IC die 1522a and 1523a. The IC die stack 152b similarly has mold compound 182b filling the interstitial space within the IC die stack 152b. As shown in FIG. 2c, the IC die 1522b is connected by bottom surface of the dual-sided bridge die 106 to the IC die 1521a. The top surface of the dual-sided bridge die 106 can be used to connect to dice of another tier or substrate or interposer (not shown) In another example, one of the IC die stacks 152a and 152b may be formed by a single die, while the other IC die stacks are formed of a plurality of tiers of IC dice. In an embodiment, the top surfaces of the IC dice 1521a and 1522b are substantially coplanar such that they are coupled with the dual-sided bridge die 106. When the IC die stacks 152a and 152b may not have a similar height, the gap fill material 116 or an IC die may be used to raise the height of a device.

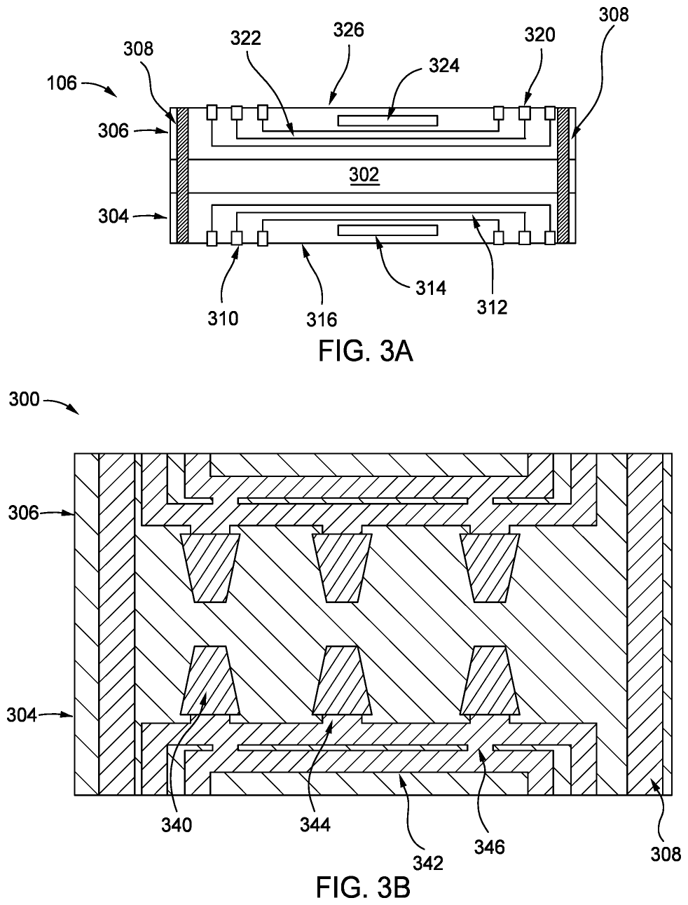

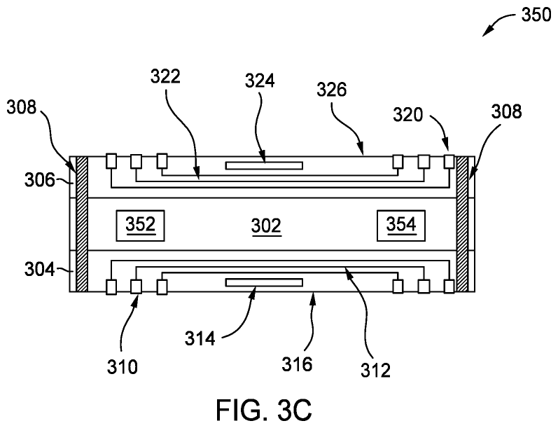

FIG. 3a illustrates a schematic cross-sectional view of a dual-sided bridge die 106, according to an embodiment. The dual-sided bridge die 106 includes a substrate 302, a bottom buildup layer 304, and a top buildup layer 306. The dual-sided bridge die 106 also includes a plurality of TSVs 308. The substrate 302 may be a silicon substrate, a glass substrate, a silicon carbide substrate, a germanium substrate, or other suitable substrate. The buildup layers 304 and 306 may also be known as a redistribution layer (RDL). The lower buildup layer 304 includes routing connections 312 coupled with hybrid bond pads 310 disposed at the bottom surface 316 of the dual-sided bridge die 106. The top buildup layer 306 includes routing connections 322 coupled with the hybrid bond pads 320 disposed on the top surface 326 of the dual-sided bridge die 106. Passive and/or active devices 314, 324 may be further integrated into the bottom buildup layer 304 and the top buildup layer 306, respectively. Some examples of passive devices 314 include capacitors, inductors, resistors, sensors, transducers, circuit protection devices, piezoelectric devices, resonators, switches and the like. Some examples of active devices 324 include diodes, rectifiers, varactors, transistors, thyristors and the like.

Each of the buildup layers 304 and 306 includes two or more metal layers that are patterned for form metal routings that define the routing connections 312 and 322. Dielectric layers are disposed between the metal layers to prevent shorting between the routing connections. The routing connections terminate at the hybrid bond pads used to form one side of the hybrid bonds 202a and 202b electrically and mechanically coupling the routing connections of the dual-sided bridge die 106 to the other dice.

According to an embodiment, the devices 314 and 324 may include passive devices, such as a capacitor, resistor, inductor, and the like, integrated in the buildup layer to improve power or signal integrity. The passive devices are coupled by the routing connections to other IC dice connected to the dual-sided bridge die 106. The passive devices are capable of improving the signal quality transmitted by the routing connections. In an embodiment, the passive devices may be disposed in the buildup layers and adjacent to the signal routing connections 312 and 322. In another embodiment, the passive devices may also be disposed in the substrate.

FIG. 3b illustrates a schematic cross-sectional view of a dual-sided bridge die 300, according to an embodiment. The dual-sided bridge die 300 includes a bottom buildup layer 304 and a top buildup layer 306. In an embodiment, the bottom buildup layer 304 and the top buildup layer 306 may have identical arrangements of routing connections and hybrid bonds. In another embodiment, the two buildup layers have different arrangements of routing connections and hybrid bonds. For brevity, FIG. 3b annotates only components of the bottom buildup layer 304. The buildup layer 304 includes a plurality of integrated passive devices 340 disposed adjacent to the routing connections 342. A first connection 344 couples the routing connections 342 with the integrated passive devices 340. The routing connections 342 may also be coupled by a second connection 346 at locations adjacent to the integrated passive devices 340. In this way, one integrated passive devices 340 may be shared by a plurality of routing connections 342.

FIG. 3c illustrates a schematic cross-sectional view of a dual-sided bridge die 350 having one or more integrated active devices, according to an embodiment. The dual-sided bridge die 350 includes one or more active devices 352 and 354. The active device 352 and 354 may be disposed in the substrate 302 or may be disposed in the buildup layers 304 or 306. The active devices may function as a memory controller circuitry, including an on-package memory controller 352 and an off-package memory controller 354. The on-package memory controller circuit 352 is configured to control memories disposed within the package 110. The off-package memory controller circuitry 354 is generally configured to control communications with memory that is not within (e.g., remote from) the chip package 110. In one example, the off-package memory controller circuitry 354 is configured to communicate through the package substrate with the one or more memory devices that are mounted to the PCB; or stated differently, memory devices that are located within the electronic device 100 but are not within the chip package 110. In addition to the active devices 352 and 354, the dual-sided bridge die 350 may also include one or more passive devices 314 and 324.

In one example, the memory controller circuitry 352 and 354 include one or more of active circuitries, such as interconnect circuitry, high bandwidth memory attached last level cache (HALL) circuitry, tag circuitry, memory circuitry, memory controller circuitry, memory devices, and direct memory access (DMA) circuitry. The silicon bridge 330 may include coherency station circuitry that includes N coherency station circuitries. The HALL circuitry includes N HALL circuitries, the tag circuitry includes N tag circuitries, and the memory controller circuitry includes N memory controller circuitries. N is greater than 1. In one example, N is 2, 4, or 8, or more.

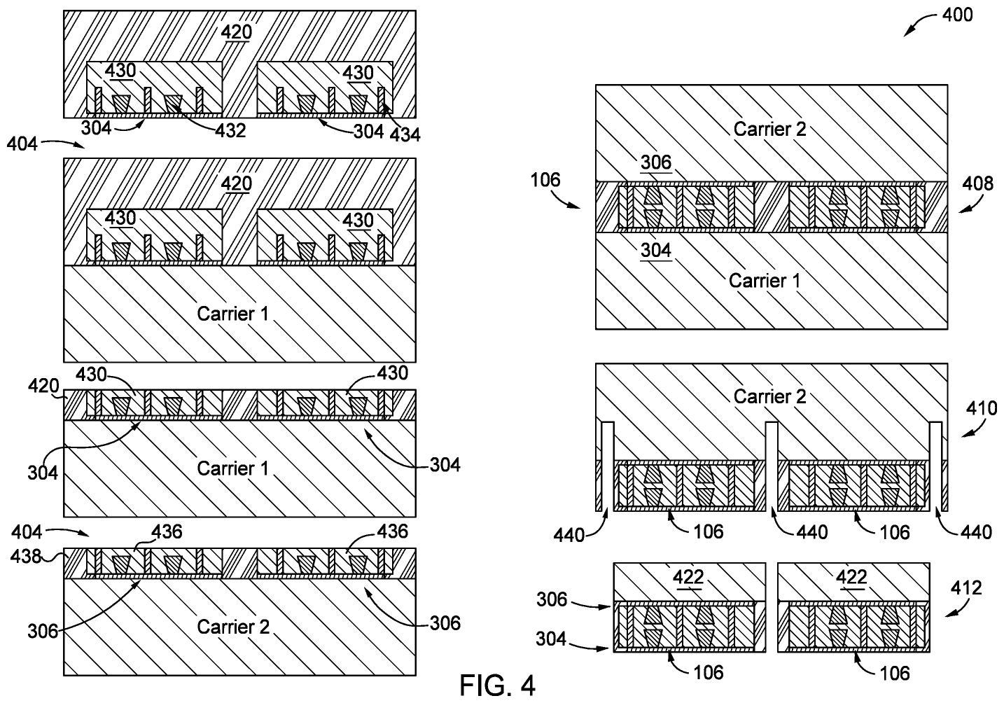

FIG. 4 is a schematic manufacturing process 400 for making a dual-sided bridge die 106, according to an embodiment of the present application. At operation 402, two single-sided bridge dice 430 are formed in a substrate 420, such as a silicon wafer. The single-sided bridge die 430 has TSVs 434, passive/active devices 432, and a buildup layer 304. The buildup layer 304 is formed on only one side of the singled-sided bridge die 430 and exposed.

At operation 404, the substrate 420 together with the singled-sided bridge dice 430 is attached to a No. 1 carrier. The buildup layer 304 contacts with the No. 1 carrier.

At operation 406, the substrate 420 at the opposite side to the buildup layer 304 is removed by using any proper methods, such as grinding, millings, or any other suitable method. The TSVs are exposed. At operation 406, another substrate 438 with two single-sided bridge dice 436 are similarly formed and attached to a No. 2 carrier. The substrate 438 and the single-sided silicon dice 436 are similarly configured as the substrate 420 and the single-sided bridge dice 430. The buildup layer 307 of the single-sided bridge dice 436 contacts with the No. 2 carrier.

At operation 408, the No. 2 carrier together with the substrate 438 is flipped. Then, the exposed sides of the single-sided bridge dice 430 and 436 are attached to each other. The TSVs of the single-sided silicon dice 430 and 436 are bonded to each other. The TSVs are connected. Operation 408 forms two dual-sided bridge dice 106 between the two carriers, each having a bottom buildup layer 304 and a top buildup layer 306.

At operation 410, the No. 1 carrier is removed, exposing the buildup layer 304. Gaps 440 are also formed to separate the two dual-sided bridge dice 106 from each other.

At operation 412, the No. 2 carrier is partially removed with a predetermined amount of spare materials 422 left on the dual-sided bridge die. The spare materials 422, as a height buffer, will be removed later when the dual-sided bridge die 106 is mounted in an IC die stack. After operation 412, individual dual-sided bridge dice 106 are formed with the spare materials 422 attached to a top surface of each dual-sided bridge die.

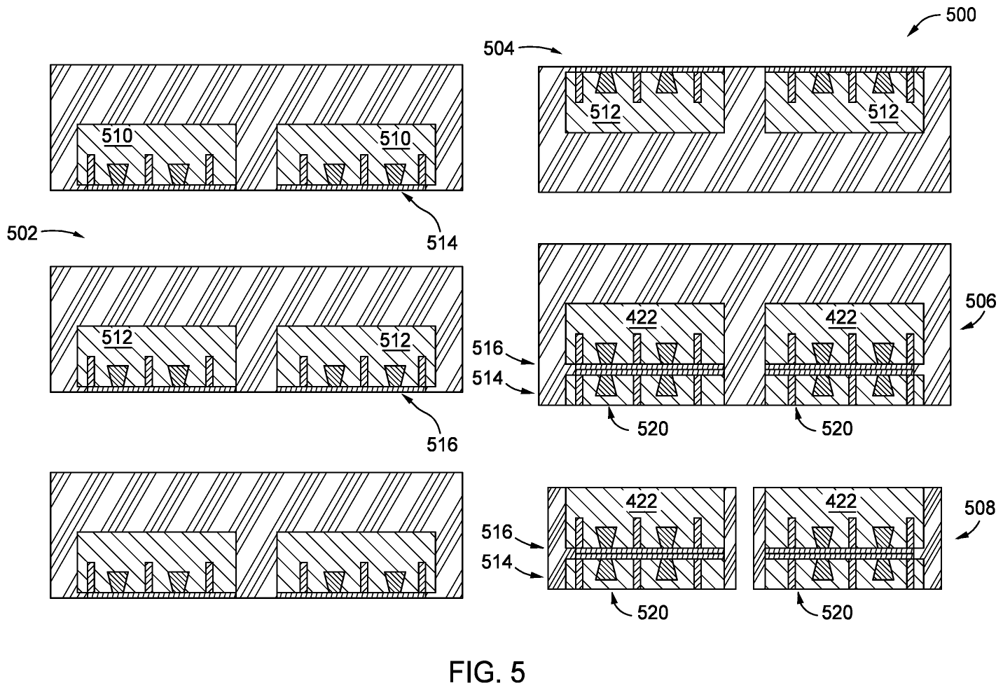

FIG. 5 is a schematic manufacturing process 500 for making a bridge die 520 having two buildup layers, according to an embodiment of the present application. Comparing to the dual-sided bridge die 106 that dispose the two buildup layers on opposite sides, the bridge die 520 has two buildup layers 514 and 516 disposed adjacent to each other. In an embodiment, the buildup layers 514 and 516 are disposed at a middle portion of the bridge die 520. Operation 502 is similar as operation 402, where two single-sided bridge dice 510 are formed in a substrate. Operation 502 forms two substrates each having two single-side bridge dice. In the single-sided bridge die 510, the buildup layer 514 is exposed. In the single-sided bridge die 512, the buildup layer 516 is also exposed.

At operation 504, the two substrates are attached to each other via the exposed buildup layers 514 and 516. Operation 504 forms a bridge die 520 with two buildup layers 514 and 516. The two buildup layers 514 and 516 are adjacent to each other and disposed in a middle part of the bridge die 520.

At operation 506, one substrate is removed, exposing the TSVs. At operation 506, the other substrate is partially removed, leaving spare materials 522 attached to one side of the bridge die 520. Gaps among the two silicon bridges 520 are also created to separates the two silicon bridges 520.

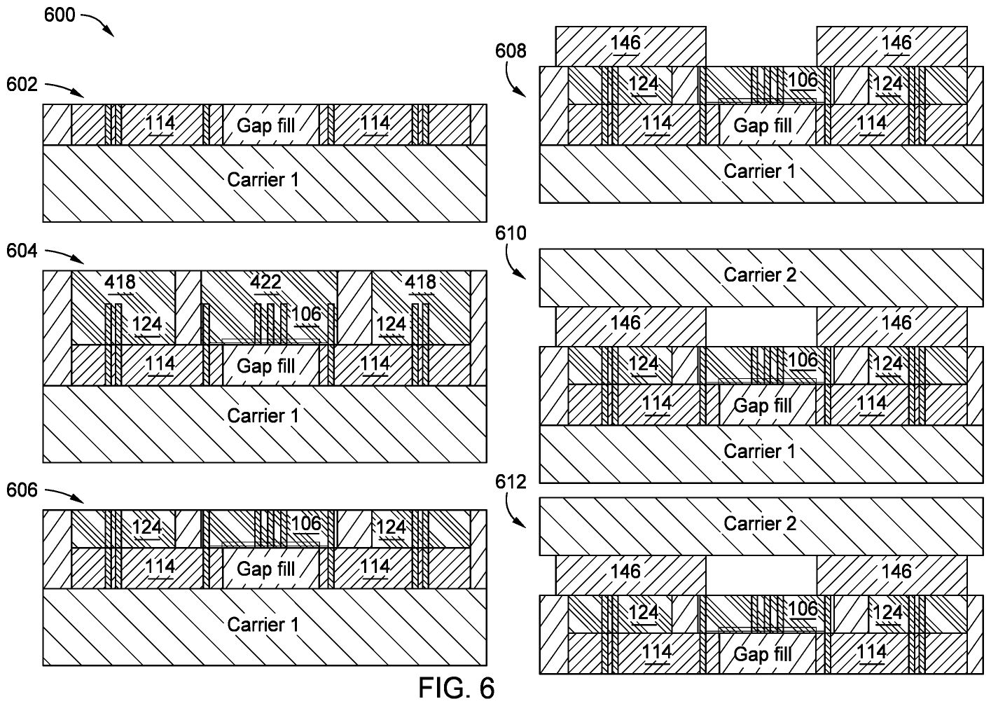

FIG. 6 is a schematic manufacturing process 600 for making an IC die stack according to an embodiment of the present application. Before operation 602, the dice 114, 124, 146 and the dual-sided bridge die 106 have been fabricated. The dice 114, 124, 146 and the dual-sided bridge die 106 may have different heights. According to an embodiment, the dice 124 and the dual-sided bridge die 106 are disposed at the same tier and include certain depths of spare materials 418 and 422, respectively. The spare materials 418 and 422 have no electrical traces or devices and are designed to be removed by proper methods, such as grinding, milling, or other processes. The spare materials 418 and 422 are disposed at an inactive side of the dice 124 and the dual-sided bridge die 106.

At operation 602, the dice 114 are mounted to a No. 1 carrier to form the first tier of IC dice. The No. 1 carrier may be made of any material that can support dice in a chip making process, such as a silicon substrate or any other suitable substrates. A gap fill material 116 is deposited in the gaps among the dice 114.

At operation 604, the dice 124 and the dual-sided bridge die 106 are mounted on top of the dice 114. Connections between the dual-sided bridge die 106 and the dice 114 are formed. More gap fill materials 116 are deposited to secure the dice 124 and the dual-sided bridge die 106.

At operation 606, the spare materials 418, 422 and the gap fill material 116 are removed by proper methods, such as grinding, milling, or any other suitable techniques. As a result, the dice 124 and the dual-sided bridge die 106 have a similar height and the TSVs are exposed. Operation 606 forms the second tier of IC dice.

At operation 608, IC dice 146 are disposed at the third tier. Connections between the dual-sided bridge die 106 and the dice 146 are formed. Operations of 602 to 608 may be repeated to add more tiers and dual-sided bridge dies to an IC die stack.

At operation 610, a No. 2 Carrier is mounted on top of the IC dice 146. The No. 2 Carrier holds together the IC die stack before the IC die stack is mounted on an interposer or a package substrate.

At operation 612, the No. 1 Carrier is removed. The bottom surface of the first tier is exposed. Now, the IC die stack can be mounted on a package substrate, an interposer, or another substrate.

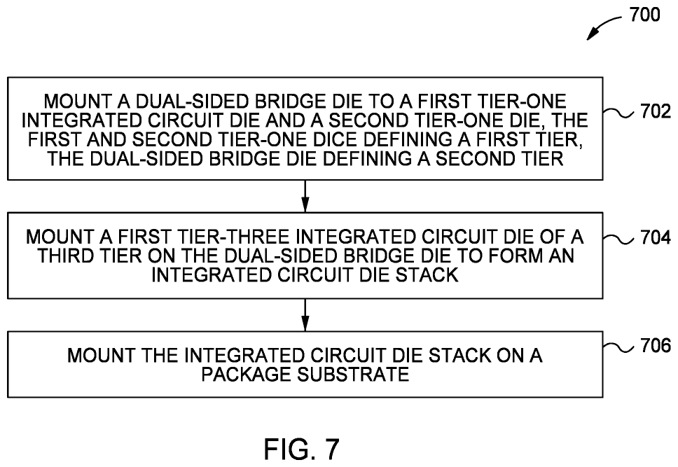

FIG. 7 illustrates a method of manufacturing an integrated circuit die stack according to an embodiment of the present application. Before operation 702, a plurality of IC dice are manufactured. A dual-side silicon bridge is also manufactured according to processes shown in FIG. 4 or 5. At operation 702, a dual-sided bridge die is mounted to a first tier-one integrated circuit die and a second tier-one die. The first and second tier-one dice defines a first tier, and the dual-sided bridge die defines a second tier. At operation 704, a first tier-three integrated circuit die of a third tier is mounted on the dual-sided bridge die to form an integrated circuit die stack. At operation 706, the integrated circuit die stack is mounted on a package substrate. The dice of each tier may be collectively handled by using a common carrier or may be individually arranged.

While the foregoing is directed to embodiments of the present invention, other and further embodiments of the invention may be devised without departing from the basic scope thereof, and the scope thereof is determined by the claims that follow.

What is claimed is:

1. A dual-sided bridge die comprising:
a substrate;
a first redistribution layer built on a top surface of the substrate and configured to couple with a bottom surface of a first integrated circuit die; and
a second redistribution layer built on a bottom surface of the substrate and configured to couple with a top surface of a second integrated circuit die,
wherein the top surface and the bottom surface of the substrate are respectively disposed on opposite sides of the substrate.

2. The dual-sided bridge die of claim 1, wherein the first and second redistribution layers comprise a plurality of hybrid bonds and routing connections.

3. The dual-sided bridge die of claim 2, wherein a pitch of the hybrid bonds is less than 10 μm.

4. The dual-sided bridge die of claim 1, further comprising a passive device and/or an active device.

5. The dual-sided bridge die of claim 1, further comprising a plurality of through silicon vias.

6. The dual-sided bridge die of claim 1, further comprising an active circuitry disposed in the substrate.

7. The dual-sided bridge die of claim 1, wherein the first redistribution layer and the second redistribution layer comprise an identical arrangement of hybrid bonds and routing connections.

8. An integrated circuit die package assembly comprising:
a package substrate; and
an integrated circuit die stack disposed above the package substrate, the integrated circuit die stack comprising:
a first tier-one integrated circuit die and a second tier-one integrated circuit die disposed at a first tier of the integrated circuit die stack;
a dual-sided bridge die disposed at a second tier that is stacked vertically above and partially overlapped with the first and second tier-one integrated circuit dice; and
a first tier-three integrated circuit die disposed at a third tier that is stacked vertically above and partially overlapped with the dual-sided bridge die disposed at the second tier,
wherein the a dual-sided bridge die is configured to provide lateral communication between at least first tier-one integrated circuit die and the second tier-one integrated circuit die.

9. The integrated circuit die package assembly of claim 8, wherein the dual-sided bridge die comprises:
a substrate;
a first redistribution layer built on a top surface of the substrate and configured to couple with a bottom surface of a first integrated circuit die; and
a second redistribution layer built on a bottom surface of the substrate and configured to couple with a top surface of a second integrated circuit die,
wherein the top surface and the bottom surface of the substrate are respectively disposed on opposite sides of the substrate.

10. The integrated circuit die package assembly of claim 9, wherein the first and second redistribution layers comprise a plurality of hybrid bonds and routing connections.

11. The integrated circuit die package assembly of claim 10, wherein a pitch of the plurality of the hybrid bonds is less than 10 μm.

12. The integrated circuit die package assembly of claim 9, wherein the dual-sided bridge die comprises a passive device and/or an active device.

13. The integrated circuit die package assembly of claim 9, wherein the dual-sided bridge die comprises a plurality of through silicon vias.

14. The integrated circuit die package assembly of claim 9, wherein the dual-sided bridge die comprises an active circuitry disposed in the substrate.

15. The integrated circuit die package assembly of claim 9, wherein the first redistribution layer and the second redistribution layer comprise an identical arrangement of hybrid bonds and routing connections.

16. The integrated circuit die package assembly of claim 8, further comprising an interposer coupling with the package substrate and the integrated circuit die stack.

17. The integrated circuit die package assembly of claim 8, further comprising:
a first tier-two integrated circuit die disposed in the second tier mounted on a top surface of the first tier and coupled to a bottom surface of the first tier-three integrated circuit die.

18. The integrated circuit die package assembly of claim 8, further comprising a filler die disposed in a fourth tier of the integrated circuit die stack, the filler die not electrically connected to the plurality of integrated circuit dice at the third tier.

19. A method of making an integrated circuit die package assembly comprising a plurality of tiers of integrated circuit dice, the method comprising:
mounting a dual-sided bridge die to a first tier-one integrated circuit die and a second tier-one die, the first and second tier-one dice defining a first tier, the dual-sided bridge die defining a second tier;
mounting a first tier-three integrated circuit die of a third tier on the dual-sided bridge die to form an integrated circuit die stack; and
mounting the integrated circuit die stack on a package substrate.

20. The method of claim 19 further comprising:
mounting a second tier-three integrated circuit die of the third tier on the dual-sided bridge die; and
mounting a filler die on the third tier, the filler die not electrically connected to the first and second tier-three integrated circuit dice of the third tier.
